(19) United States
(12) Patent Application Publication
(10) Pub. No.: US 2007/0029656 A1
(43) Pub. Date: Feb. 8, 2007

(54) SEMICONDUCTOR DEVICE

(75) Inventor: Tomoharu Fujii, Nagano-shi, Nagano (JP)

Correspondence Address: RANKIN, HILL, PORTER & CLARK LLP, 4080 ERIE STREET, WILLOUGHBY, OH, 44094-7836, US

(73) Assignee: SHINKO ELECTRIC INDUSTRIES CO., LTD., Nagano-shi (JP)

(21) Appl. No.: 11/462,196

(22) Filed: Aug. 3, 2006

(30) Foreign Application Priority Data
Aug. 5, 2005 (JP) 2005-227638

(51) Int. Cl. H01L 23/02

(52) U.S. Cl. 257/679

(57) ABSTRACT

Electronic parts 12, 13 and a terminal 14 are provided on a substrate 11, an upper surface 18A of a terminal main body portion 18 is set higher than surfaces 12A, 13A of the electronic parts 12, 13, a sealing resin is provided to expose the upper surface 18A of the terminal main body portion 18, and the terminal 14 and the wiring pattern 16 are connected directly to each other.

### TECHNICAL FIELD

The present disclosure relates to a semiconductor device and, more particularly, a semiconductor device having a wiring pattern formed on a sealing resin and a terminal sealed with the sealing resin and connected electrically to the wiring pattern.

### RELATED ART

Among the semiconductor devices in the related art, there are some semiconductor devices in which the wiring patterns are provided on the sealing resin that seals the electronic parts, and the wiring patterns and the terminals formed on the substrate are connected electrically mutually via the vias, or the like (see FIG. 11).

FIG. 11 is a sectional view of a semiconductor device in the related art.

As shown in FIG. 11, a semiconductor device 100 has a substrate 101, an electronic parts 103, a sealing resin 104, vias 105, and a wiring pattern 106.

The substrate 101 has terminals 102 and wiring patterns (not shown). The terminals 102 are connected electrically to the electronic parts 103. Also, a height of the terminals 102 is set lower than that of the electronic parts 103.

The electronic parts 103 is provided on the substrate 101, and is connected electrically to the wiring patterns (not shown) provided on the substrate 101.

The sealing resin 104 is provided to cover the terminals 102 and the electronic parts 103. Opening portions 104A to expose the terminals 102 are formed in the sealing resin 104. The opening portions 104A are formed by the laser.

The vias 105 are provided in the opening portions 104A. The vias 105 are connected electrically to the terminals 102. The wiring pattern 106 is provided on the sealing resin 104, and is connected electrically to the vias 105 (see Patent Literature 1: Japanese Patent unexamined Publication No. 2002-158312, for example).

However, since a thickness of the sealing resin 104 formed on the terminals 102 is large in the semiconductor device 100, the opening portions 104A are formed in the sealing resin 104 by using the expensive laser beam machining. Therefore, such a problem existed that a cost of the semiconductor device 100 is increased.

### SUMMARY

Embodiments of the present invention provide a semiconductor device capable of reducing a cost.

According to an aspect of one or more embodiments of the present invention, there is provided a semiconductor device, which includes a substrate; an electronic parts provided on the substrate; a terminal provided on the substrate and connected electrically to the electronic parts; a sealing resin for sealing the electronic parts and the terminal; and a wiring pattern provided on the sealing resin and connected electrically to the terminal; wherein the terminal is formed like a column, and the sealing resin is provided to expose an upper surface of the terminal, and the wiring pattern and the terminal are connected directly to each other.

According to one or more embodiments of the present invention, since the sealing resin is provided to expose the upper surface of the terminal and the wiring pattern and the terminal are connected directly to each other, it is not needed to provide the via between the wiring pattern and the terminal. Therefore, a cost (including a production cost) of the semiconductor device can be reduced.

According to another aspect of one or more embodiments of the present invention, there is provided a semiconductor device, which includes a substrate; an electronic parts provided on the substrate; a terminal provided on the substrate and connected electrically to the electronic parts; a sealing resin for sealing the electronic parts and the terminal; and a wiring pattern provided on the sealing resin and connected electrically to the terminal via a via; wherein the terminal is formed like a column.

According to one or more embodiments of the present invention, since a thickness of the sealing resin on the terminal main body portion is made thin by shaping the terminal into a column, the opening portion in which the via is provided can be formed by the drilling that is more inexpensive than the laser beam machining. Therefore, a production cost of the semiconductor device can be reduced.

Various implementations may include one or more the following advantages. For example, a cost of the semiconductor device can be reduced.

Other features and advantages may be apparent from the following detailed description, the accompanying drawings and the claims.

### BRIEF DESCRIPTION OF THE DRAWINGS

FIG. 1 is a sectional view of a semiconductor device according to a first embodiment of the present invention.

FIG. 2 is an enlarged view of the semiconductor device corresponding to an area A shown in FIG. 1.

FIG. 3 is a sectional view of a semiconductor device according to a variation of the first embodiment.

FIG. 4 is a view (#1) showing steps of manufacturing the semiconductor device according to the first embodiment.

FIG. 5 is a view (#2) showing steps of manufacturing the semiconductor device according to the first embodiment.

FIG. 6 is a view (#3) showing steps of manufacturing the semiconductor device according to the first embodiment.

FIG. 7 is a view (#4) showing steps of manufacturing the semiconductor device according to the first embodiment.

FIG. 8 is a view (#5) showing steps of manufacturing the semiconductor device according to the first embodiment.

FIG. 9 is a view (#6) showing steps of manufacturing the semiconductor device according to the first embodiment.

FIG. 10 is a sectional view of a semiconductor device according to a second embodiment of the present invention.

FIG. 11 is a sectional view of a semiconductor device in the related art.

### DETAILED DESCRIPTION

Next, embodiments of the present invention will be explained with reference to the drawings hereinafter.

(First Embodiment)

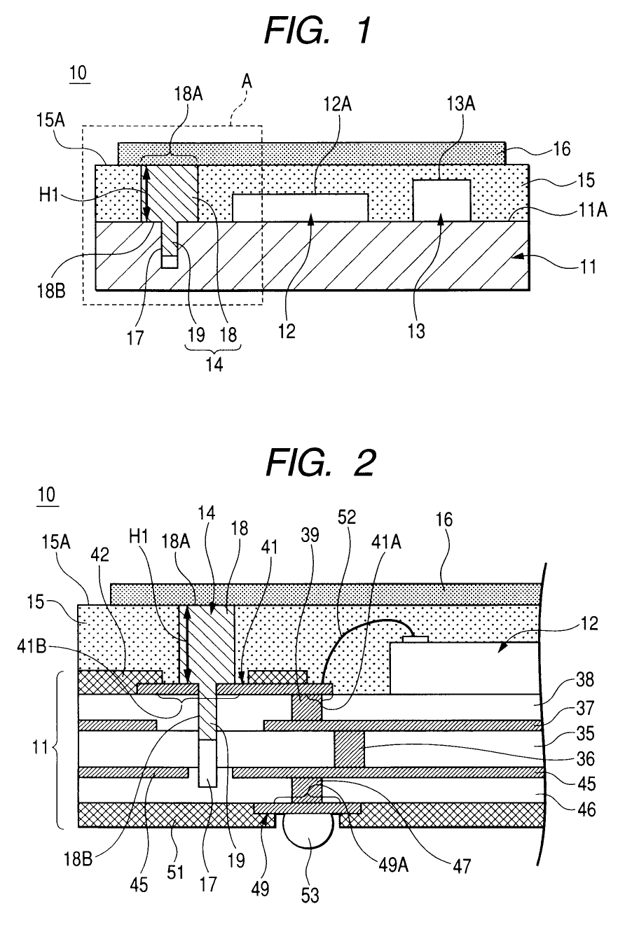

FIG. 1 is a sectional view of a semiconductor device according to a first embodiment of the present invention, and FIG. 2 is an enlarged view of the semiconductor device corresponding to an area A shown in FIG. 1.

A semiconductor device 10 according to the first embodiment of the present invention will be explained with reference to FIG. 1 and FIG. 2 hereunder. In FIG. 1, H1 denotes a height from an upper surface 11A of a substrate 11 to an upper surface 18A of a terminal main body portion 18 (referred to as a “height H1” hereinafter).

A semiconductor device 10 has a substrate 11, electronic parts 12, 13, a terminal 14, a sealing resin 15, and a wiring pattern 16.

The substrate 11 has resin layers 35, 38, 46, vias 36, 39, 47, wirings 37, 41, 45, 49, and protection films 42, 51. The via 36 is provided to pass through the resin layer 35, and connects electrically the wiring 37 and the wiring 45. The wiring 37 is provided on an upper surface of the resin layer 35. The resin layer 38 is provided on an upper surface of the resin layer 35 to cover the wiring 37. The via 39 is provided in the resin layer 38 on the wiring 37. The via 39 is connected electrically to the wiring 37. The wiring 41 is provided on the resin layer 38, and is connected electrically to the wiring 39. The wiring 41 has a connecting portion 41A to which a wire 52 is connected, and a terminal connecting portion 41B to which the terminal 14 is connected. The wiring 41 is connected electrically to the terminal 14 and also connected electrically to the electronic parts 12 via the wire 52. The protection film 42 is provided on the resin layer 38 to cover the wiring 41 except the connecting portion 41A and the terminal connecting portion 41B.

The wiring 45 is provided on a lower surface of the resin layer 35 and is connected electrically to the via 36. The resin layer 46 is provided on a lower surface of the resin layer 35 to cover the wiring 45. The via 47 is provided in the resin layer 46 and is connected electrically to the wiring 45 and the wiring 49. The wiring 49 is provided on a lower surface of the resin layer 46. The wiring 49 has a connecting portion 49A to which an external connection terminal 53 is connected. The protection film 51 is provided on a lower surface of the resin layer 46 to cover the wiring 49 except the connecting portion 49A. The external connection terminal 53 is provided on the connecting portion 49A that is exposed from the protection film 51.

Also, an opening portion 17 that passes through the wiring 41 and the resin layers 35, 38 to reach the resin layer 46 is formed in the substrate 11. An insertion portion 19 of the terminal 14 is inserted into this opening portion 17.

Since the opening portion 17 is formed in the substrate 11 in this manner, a position of the terminal 14 can be regulated in inserting the insertion portion 19 of the terminal 14 into the opening portion 17. In FIG. 2, the opening portion 17 passing through the wiring 41 and the resin layers 35, 38 to reach the resin layer 46 is illustrated as an example. Actually a depth of the opening portion 17 depends on a length of the insertion portion 19 of the terminal 14. Also, for example, when a diameter of the insertion portion 19 is 0.2 mm, a diameter of the opening portion 17 can be set to 0.3 mm.

The electronic parts 12, 13 are provided on the substrate 11. The electronic parts 12 is connected electrically to the connecting portion 41A of the wiring 41 via the wire 52. The electronic parts 13 is connected electrically to the wiring (not shown) formed on the resin layer 38. The electronic parts 12, 13 are the parts such as the semiconductor chip, the chip parts, or the like, for example.

The terminal 14 is provided on the terminal connecting portion 41B in a state that its insertion portion 19 is inserted into the opening portion 17. The terminal 14 is connected electrically to the wiring 41. The terminal 14 is connected electrically to the electronic parts 12, 13 via the wiring 41.

The terminal 14 has the terminal main body portion 18 and the insertion portion 19. The terminal main body portion 18 is formed like a column. More concretely, the terminal main body portion 18 may be shaped like a square column or a round column, for example. The upper surface 18A of the terminal main body portion 18 is exposed from the sealing resin 15. The upper surface 18A of the terminal main body portion 18 is connected directly to the wiring pattern 16.

In this manner, since the upper surface 18A of the terminal main body portion 18 is exposed from the sealing resin 15, there is no need for provision of the via that connects electrically the terminal 14 and the wiring pattern 16. Therefore, a cost (including a production cost) of the semiconductor device 10 can be reduced.

Also, the height H1 of the terminal main body portion 18 is set such that the upper surface 18A of the terminal main body portion 18 becomes higher than upper surfaces 12A, 13A of the electronic parts 12, 13.

In this manner, since the height H1 of the terminal main body portion 18 is set such that the upper surface 18A of the terminal main body portion 18 becomes higher than upper surfaces 12A, 13A of the electronic parts 12, 13, it can be prevented that the upper surfaces 12A, 13A of the electronic parts 12, 13 are exposed from the sealing resin 15. Here, the surfaces 12A, 13A are surfaces of the electronic parts 12, 13 on the opposite side to surfaces of the electronic parts 12, 13 opposing to the substrate 11. The height H1 of the terminal main body portion 18 can be set 1 mm to 1.5 mm, for example. Also, when the terminal main body portion 18 is shaped as the round column, a diameter of the terminal main body portion 18 can be set to 1 mm, for example. The aspect ratio of the terminal main body portion 18 (Height/Diameter) is equal or more than 1.5.

The insertion portion 19 is formed as a rod, and is provided on a lower surface 18B of the terminal main body portion 18. More concretely, the insertion portion 19 may be shaped like a square column or a round column, for example. The insertion portion 19 is formed integrally with the terminal main body portion 18. The insertion portion 19 is inserted into the opening portion 17.

In this manner, since the insertion portion 19 is provided to the terminal 14, a position of the terminal 14 can be regulated by inserting the insertion portion 19 into the opening portion 17 formed in the substrate 11. In this case, not only is the insertion portion 19 merely inserted into the opening portion 17, but also the terminal 14 may be fixed to the substrate 11 by applying the solder (not shown) to a space between the terminal 14 and the wiring 41 and/or the substrate 11 in which the opening portion 17 is formed.

A length of the insertion portion 19 can be set to 0.5 mm, for example. Also, when the insertion portion 19 is shaped into a round column, a diameter of the insertion portion 19 can be set to 0.2 mm, for example.

As the material of the terminal 14, for example, a conductive metal can be employed. As the conductive metal, Cu, Cu alloy, or Fe—Ni alloy is preferable. Also, the terminal 14 can be formed, for example, by applying the press working to a metal plate or a metal wire made of the conductive metal.

The sealing resin 15 is provided on the substrate 11. The sealing resin 15 seals the electronic parts 12, 13 but exposes the upper surface 18A of the terminal main body portion 18. Also, an upper surface 15A of the sealing resin 15 together with the upper surface 18A of the terminal main body portion 18 is constructed to constitute an almost same flat plane. As the sealing resin 15, a mold resin formed by the transfer molding method using dies, for example, can be employed. A thickness of the sealing resin 15 can be set to 1 mm to 1.5 mm, for example.

The wiring pattern 16 is provided on the sealing resin 15. The wiring pattern 16 is connected directly to the terminal main body portion 18 exposed from the sealing resin 15. In this way, if the terminal 14 and the wiring pattern 16 are connected directly, the reliability of the electrical connection between the terminal 14 and the wiring pattern 16 can be improved.

As the material of the wiring pattern 16, for example, Cu can be employed. Also, when the semiconductor device 10 is employed as a radio module, the wiring pattern 16 is used as an antenna, for example.

According to the semiconductor device of the present embodiment, the sealing resin 15 is provided to expose the upper surface of the terminal and the wiring pattern 16 and the terminal 14 are connected directly. Therefore, a cost (including a production cost) of the semiconductor device 10 can be reduced. Also, since the insertion portion 19 is provided to the terminal 14, a position of the terminal 14 can be restrained by inserting the insertion portion 19 into the opening portion 17 formed in the substrate 11.

A plurality of insertion portions 19 may be provided on the lower surface 18B of the terminal main body portion 18.

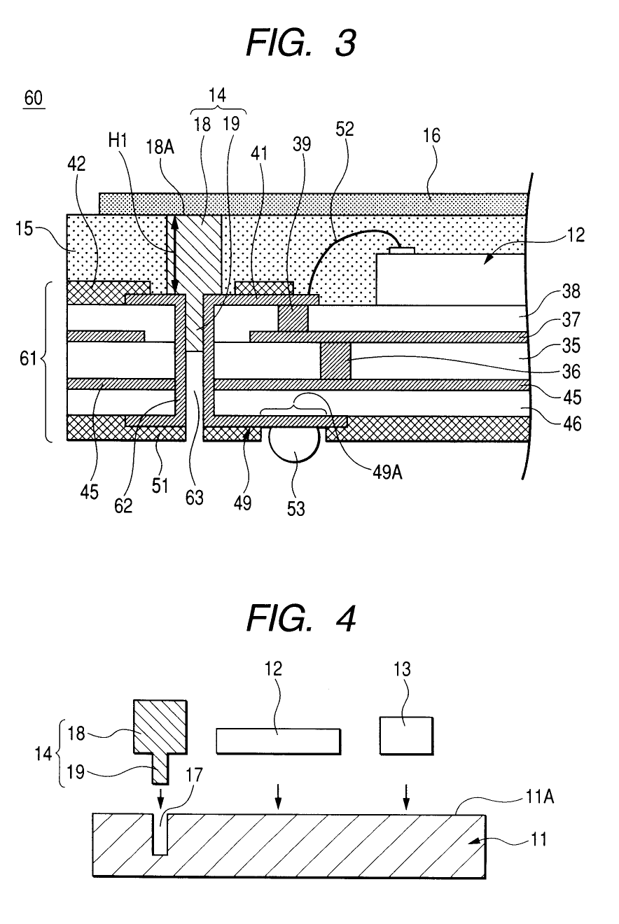

FIG. 3 is a sectional view of a semiconductor device according to a variation of the first embodiment. In FIG. 3, the same reference symbols are affixed to the same constituent portions as those of the semiconductor device 10 of the first embodiment, and their explanation will be omitted herein.

As shown in FIG. 3, a semiconductor device 60 is constructed similarly to the semiconductor device 10 according to the first embodiment except that a substrate 61 is provided instead of the substrate 11 provided to the semiconductor device 10.

The substrate 61 is constructed similarly to the substrate 11 explained in the first embodiment except that a through via 62 is further provided. The through via 62 is provided to pass through the substrate 61. The through via 62 connect electrically the wiring 41 and the wiring 49. A through hole 63 passing through the substrate 61 is formed in a center portion of the through via 62. The insertion portion 19 of the terminal 14 is inserted into the through hole 63. The through via 62 can be formed by depositing a conductive layer (e.g., Cu) on an inner wall of the through hole (not shown) passing through the substrate 61 by means of the plating method.

In this manner, in the semiconductor device 60 in which the insertion portion 19 of the terminal 14 is inserted into the through hole 63 passing through the substrate 61, the same advantages as the semiconductor device 10 of the first embodiment can be achieved. Also, the terminal 14 may be fixed to the substrate 61 by applying the solder (not shown) to a space between the through via 62 and the insertion portion 19 and/or a space between the terminal main body portion 18 and the wiring 41.

FIG. 4 to FIG. 9 are views showing steps of manufacturing the semiconductor device according to the first embodiment. In FIG. 4 to FIG. 9, the same reference symbols are affixed to the same constituent portions as those of the semiconductor device 10 explained in FIG. 1 and FIG. 2 herein.

The method of manufacturing the semiconductor device according to the first embodiment will be explained with reference to FIG. 4 to FIG. 9 hereunder. Here, following explanation will be made by taking as an example the case where a plurality of semiconductor devices 10 are manufactured on the substrate 11 having a plurality of semiconductor device forming areas in which the semiconductor device 10 is formed.

At first, as shown in FIG. 4, the opening portion 17 is formed in the substrate 11 from the upper surface 11A side of the substrate 11. The opening portion 17 is formed by the drilling, or the like, for example.

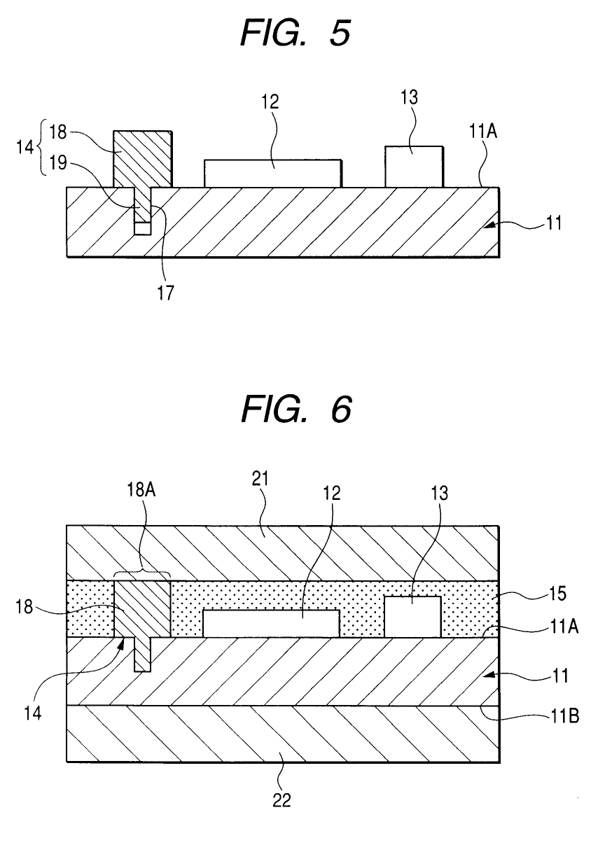

Then, as shown in FIG. 5, the electronic parts 12, 13 are mounted on the substrate 11 and connected to the wiring (not shown) Also, the terminal 14 is fixed to the substrate 11 by inserting the insertion portion 19 into the opening portion 17. At this time, the insertion portion 19 may be fixed to the substrate 11 by applying the solder to a space between the insertion portion 19 and the opening portion 17.

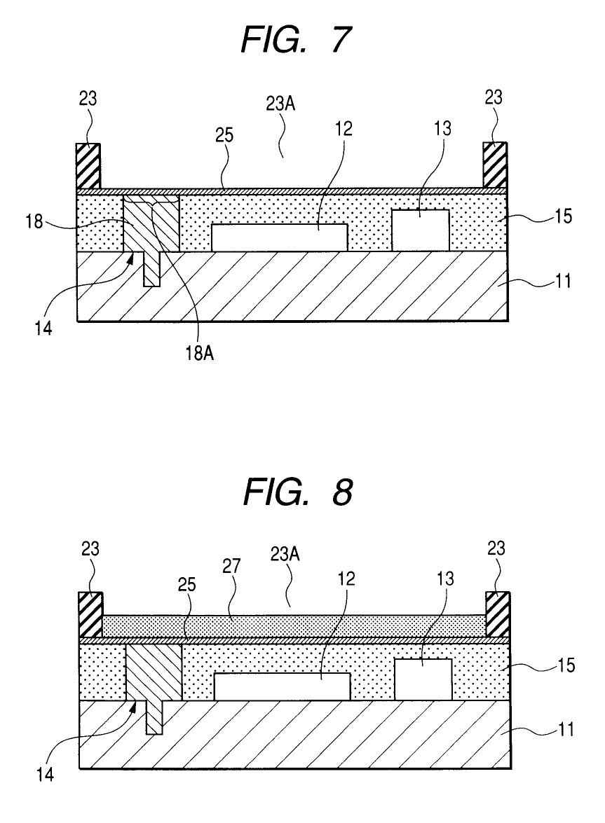

Then, as shown in FIG. 6, a lower die 22 is brought into contact with a lower surface 11B of the substrate 11, then a resin tablet (not shown) is arranged the structural body shown in FIG. 5, and then an upper die 21 is moved such that this upper die 21 comes in contact with the upper surface 18A of the terminal main body portion 18. Thus, the sealing resin 15 is formed to expose the upper surface 18A of the terminal main body portion 18.

At this time, when the sealing resin 15 is left on the terminal main body portion 18, this sealing resin 15 is polished until the upper surface 18A of the terminal main body portion 18 is exposed.

Then, as shown in FIG. 7, a seed layer 25 is formed to cover an upper surface of the structural body (except the upper die 21 and the lower die 22) shown in FIG. 6, and then a resist layer 23 having an opening portion 23A is formed. The opening portion 23A is an opening portion that exposes a portion of the seed layer 25 corresponding to the forming position of the wiring pattern 16. The seed layer 25 can be formed by the electroless plating method, the sputter method, the vapor deposition method, or the like, for example. Also, as the material of the seed layer 25, Cu can be employed, for example.

Then, as shown in FIG. 8, a conductive metal 27 is deposited on the seed layer 25, which is exposed from the opening portion 23A, by the electroplating method. As the conductive metal 27, for example, Cu can be employed. The resist layer 23 is removed by a resist removing liquid after the conductive metal 27 is formed.

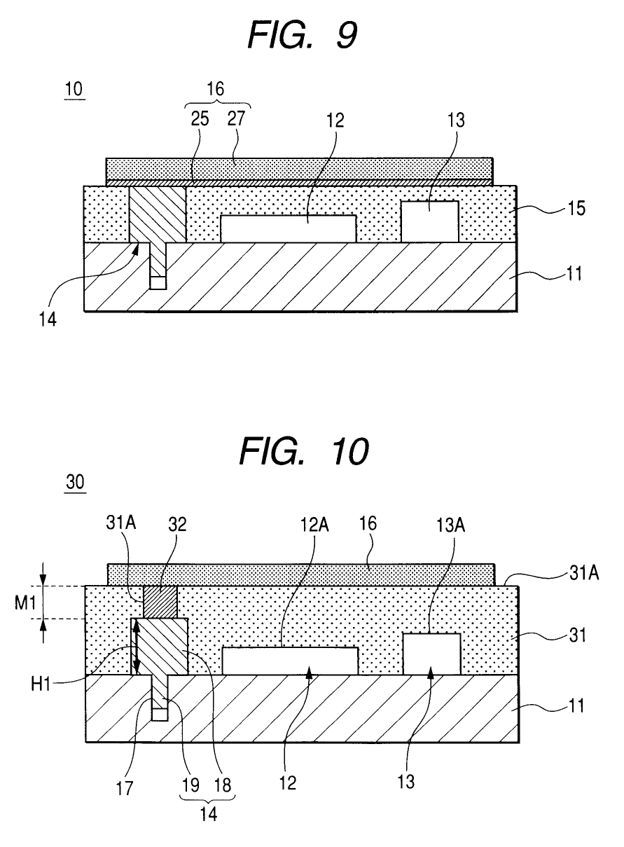

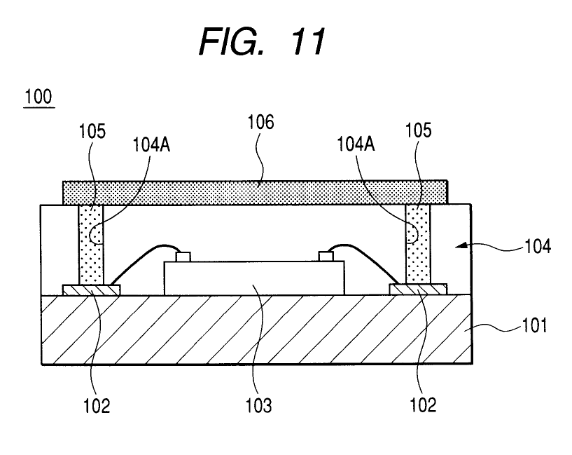

Then, as shown in FIG. 9, the unnecessary seed layer 25 on which the conductive metal 27 is not formed is removed. Thus, the wiring pattern 16 consisting of the seed layer 25 and the conductive metal 27 is formed. The structural bodies formed in plural semiconductor device forming areas are divided into individual pieces by cutting the substrate 11 and the sealing resin 15. As a result, a plurality of semiconductor devices 10 are manufactured.

According to the method of manufacturing the semiconductor device of the present embodiment, since it is not needed that the via for connecting electrically the terminal 14 and the wiring pattern 16 should be provided, a production cost of the semiconductor device can be reduced by omitting the via forming step. In this case, the wiring pattern 16 may be formed by patterning the conductive metal film after this conductive metal film is formed by the sputter method, or the like.

(Second Embodiment)

FIG. 10 is a sectional view of a semiconductor device according to a second embodiment of the present invention.

A semiconductor device 30 according to the second embodiment of the present invention will be explained with reference to FIG. 10 hereunder. In FIG. 10, M1 is a thickness of a sealing resin 31 formed on the terminal main body portion 18 (referred to as a “thickness M1” hereinafter). Also, in FIG. 10, the same reference symbols are affixed to the same constituent portions as those of the semiconductor device 10 of the first embodiment, and their explanation will be omitted herein.

The semiconductor device 30 is constructed similarly to the semiconductor device 10 of the first embodiment except that the sealing resin 31 is provided instead of the sealing resin 15 provided to the semiconductor device 10 of the first embodiment and a via 32 is provided newly.

The sealing resin 31 is provided on the substrate 11 and seals the electronic parts 12, 13 and the terminal 14. An opening portion 31A used to provide the via 32 is formed in the sealing resin 31 on the terminal main body portion 18. The opening portion 31A is an opening portion that exposes the upper surface 18A of the terminal main body portion 18.

Also, the thickness M1 of the sealing resin 31 on the terminal main body portion 18 is set to 100 μm to 300 μm (a depth of the opening portion 31A is 100 μm to 300 μm) such that the opening portion 31A can be formed by the drilling.

Normally almost 100 μm is required as a positional precision of the drill in the vertical direction (depth direction). Therefore, if the thickness M1 of the sealing resin 31 is smaller than 100 μm, it is difficult to form the opening portion 31A by using the drill. Also, the sealing resin 31 is solid and is hard to work, for this sealing resin 31 is used to protect the electronic parts 12, 13 from the impact applied from the outside, or the like. Therefore, if the thickness M1 of the sealing resin 31 is larger than 300 μm, it is difficult to form the opening portion 31A by using the drill.

Accordingly, since the thickness M1 of the sealing resin 31 on the terminal main body portion 18 is set to 100 μm to 300 μm, the opening portion 31A can be formed by the drilling that is more inexpensive than the laser beam machining. Therefore, a production cost of the semiconductor device 30 can be reduced. In this case, the material similar to the sealing resin 15 in the first embodiment can be employed as the sealing resin 31. Also, the sealing resin 31 can be formed by using the same approach (for example, the transfer molding method using the dies) as that applied to form the sealing resin 15 in the first embodiment.

The via 32 is provided in the opening portion 31A. One end portion of the via 32 is connected to the terminal main body portion 18, and the other end portion is connected to the wiring pattern 16. As the material of the via 32, for example, Cu can be employed. Also, the via 32 can be formed by the electroplating method using the terminal 14 as a power feeding layer, for example.

According to the semiconductor device of the second embodiment, since the thickness M1 of the sealing resin 31 on the terminal main body portion 18 is set to 100 μm to 300 μm, the opening portion 31A can be formed by the drilling that is more inexpensive than the laser beam machining. As a result, a production cost of the semiconductor device 30 can be reduced. In this case, the semiconductor device 30 of the second embodiment can be manufactured by the same approach as that applied to the semiconductor device 10 of the first embodiment except that the opening portion 31A is formed in the sealing resin 31 by the drilling and then the via 32 is formed by the electroplating method using the terminal main body portion 18 as a power feeding layer.

With the above, the preferred embodiments of the present invention are described in detail. But the present invention is not limited to such particular embodiments, and various variations/modifications can be applied within a scope of the gist of the present invention set forth in claims.

Also, the first and second embodiments can be applied to the semiconductor device in which the external connecting terminals are provided to the substrate 11.

The present invention can be applied to the semiconductor device that is capable of reducing a cost.

What is claimed is:

1. A semiconductor device, comprising:
a substrate;
an electronic parts provided on the substrate;
a terminal provided on the substrate and connected electrically to the electronic parts;
a sealing resin for sealing the electronic parts and the terminal; and
a wiring pattern provided on the sealing resin and connected electrically to the terminal,
wherein the terminal is formed like a column, and
the sealing resin is provided to expose an upper surface of the terminal, and the wiring pattern and the terminal are connected directly to each other.

2. A semiconductor device, comprising:
a substrate;
an electronic parts provided on the substrate;
a terminal provided on the substrate and connected electrically to the electronic parts;
a sealing resin for sealing the electronic parts and the terminal; and
a wiring pattern provided on the sealing resin and connected electrically to the terminal via a via,
wherein the terminal is formed like a column.

3. A semiconductor device according to claim 1, wherein the upper surface of the terminal is set higher than a surface of the electronic parts on an opposite side to a surface of the electronic parts opposing to the substrate.

4. A semiconductor device according to claim 2, wherein an upper surface of the terminal is set higher than a surface of the electronic parts on an opposite side to a surface of the electronic parts opposing to the substrate.

5. A semiconductor device according to claim 1, wherein the sealing resin is formed by a transfer molding method using dies.

6. A semiconductor device according to claim 2, wherein the sealing resin is formed by a transfer molding method using dies.

7. A semiconductor device according to claim 1, wherein the terminal has a terminal main body portion connected electrically to the wiring pattern, and an insertion portion that is inserted into the substrate.

8. A semiconductor device according to claim 2, wherein the terminal has a terminal main body portion connected electrically to the wiring pattern, and an insertion portion that is inserted into the substrate.

9. A semiconductor device according to claim 7, wherein an opening portion into which the insertion portion is inserted is provided in the substrate.

10. A semiconductor device according to claim 8, wherein an opening portion into which the insertion portion is inserted is provided in the substrate.

11. A semiconductor device according to claim 7, wherein the substrate has a through hole passing therethrough, and the insertion portion of the terminal is inserted into the through hole.

12. A semiconductor device according to claim 8, wherein the substrate has a through hole passing therethrough, and the insertion portion of the terminal is inserted into the through hole.

13. A semiconductor device according to claim 11, wherein a through via is formed on an inner wall of the through hole.

14. A semiconductor device according to claim 12, wherein a through via is formed on an inner wall of the through hole.

15. A method of manufacturing a semiconductor device, comprising steps of:
providing an electronic parts and a terminal formed like a column on a substrate and connecting electrically the terminal to the electric parts;
sealing the electronic parts and the terminal by a sealing resin so as to expose an upper surface of the terminal; and
providing a wiring pattern provided on the sealing resin and connecting electrically the wiring pattern to the terminal.

16. A method of manufacturing a semiconductor device according to claim 15, wherein the sealing step includes polishing the sealing resin until the upper surface of the terminal is exposed after the sealing.

17. A method of manufacturing a semiconductor device according to claim 16, further comprising a step of:
forming an opening portion in the sealing resin above the terminal after the sealing and providing a via in the opening portion of the sealing resin.
